(19) United States
(12) Patent Application Publication
(10) Pub. No.: US 2004/0109374 A1
(43) Pub. Date: Jun. 10, 2004

(54) Failure tolerant parallel power source configuration

(76) Inventor: Rajagopalan Sundar, San Diego, CA (US)

Correspondence Address: HOWREY SIMON ARNOLD & WHITE, LLP - OC, 301 RAVENSWOOD AVENUE, BOX 34, MENLO PARK, CA, 94025, US

(21) Appl. No.: 10/658,673

(22) Filed: Sep. 8, 2003

Related U.S. Application Data
(60) Provisional application No. 60/410,392, filed on Sep. 12, 2002.

(51) Int. Cl. G11C 5/06

(52) U.S. Cl. 365/226; 365/63

(57) ABSTRACT

A system comprising a plurality of power sources coupled in parallel is described. The sources are each coupled to a first bus and to a second bus. A sensing element corresponding to each power source is coupled to a third bus, and allows sensing of power demanded by a load from the source. Each source is configured to sense the power demanded from it by the load, and, in response thereto, supply power to the load. In one embodiment, a sensing element comprises a resistor having a resistance inversely proportional to the power capacity of its corresponding source. In the event of a power failure of a power source, an interlock responsive to the failure condition interrupts current flow through the sensing element corresponding to the failed source, and optionally disconnects the power source from the load.

This application claims the benefit of U.S. Provisional Application No. 60/410,392 filed Sep. 12, 2002, which is hereby fully incorporated by reference herein as though set forth in full.

### BACKGROUND OF THE INVENTION

1. Field of the Invention

This invention relates generally to parallel power sources, and more specifically, to a configuration of parallel power sources capable of powering a load which is tolerant of failure of individual ones of the power sources.

2. Related Art

In electrical power systems, it is often desirable to connect power sources in parallel in order to increase the power capacity and/or failure tolerance of the system. Feedback from a load may indicate the power demand of the load. The power supplied by individual ones of the parallel combination may be adjusted in response to the demand from the load. Load balancing may be achieved by adjusting the power supplied by an individual power source according to its power capacity.

Conventional parallel configurations of power sources are susceptible to several problems. One such problem is that these configurations are subject to single point failures of the feedback path from the load back to the parallel combination. If the feedback path is severed or disrupted for any reason, the entire parallel combination shuts down. For example, in a master/slave configuration, whereby one of the power sources acts as the master and the rest are master/slave configuration, whereby one of the power sources acts as the master and the rest are slaves, the slaves are regulated by, and therefore dependent on, the master. If the master goes down, the entire system goes down.

Another such problem is that slight variations in the individual power sources can lead to an unbalanced condition, whereby one or more of the sources may operate at or near maximum capacity while the remaining sources are idle or furnish little or no load current. If allowed to occur over a long period of time, this unbalanced condition subjects the sources under load to accelerated thermal and electrical stress.

A representative conventional parallel power source system is disclosed in U.S. Pat. No. 6,157,555. In this system, a central feedback loop senses the load current delivered by the system, and mutually communicates a control signal derived from the load current to individual regulators in each of the parallel sources. In response to the control signal, each power supply regulates its output to contribute a substantially equal amount of current to the load, thereby balancing the system without having to rely on current matching to a particular master power source. However, because the individual regulators share a common control signal, this system is susceptible to single point failure in that a malfunction in the circuitry comprising the load current sensor or the central feedback loop can potentially affect the output of every source in the parallel scheme.

### SUMMARY

A system comprising a plurality of power sources coupled in parallel is described. The sources are each coupled to a first bus and to a second bus. A power sensing element corresponding to each power source is provided, and each power sensing element allows sensing of power demanded by the load from its corresponding source. Each power sensing element is coupled to a third bus. Each source is configured to sense power demanded from it by the load, and, in response thereto, supply power to the load. If one of the sensing elements fails, the other power supplies will still be able to sense load demand. In the event of a power failure of a power source, in one embodiment, an interlock responsive to the failure condition interrupts current flow through the sensing element corresponding to the failed source, and optionally disconnects the power source from the load. The system is thus resistant to single point failures.

The parallel system may comprise identical or disparate individual power sources. In one embodiment, the system comprises a plurality of AC or DC power sources. The parallel system may also comprise individual power sources having identical or disparate power capacities. In one embodiment, one or more of the sources are fuel cells.

The power sensing elements may be coupled external to the power sources, or may be located internal to each power source. For an AC power source, the corresponding power sensing element may allow sensing of load current magnitude and phase. For a DC power source, the corresponding power sensing element may allow sensing of the magnitude of the load current. The power sensing element may comprise any suitable instrument, such as a resistor, an inductive current transducer, or a Hall effect current transducer. In one embodiment, a power sensing element comprises a resistor having a resistance inversely proportional to the power capacity of its corresponding source.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE FIGURES

The invention can be better understood with reference to the following figures. The components in the figures are not necessarily to scale, emphasis instead being placed upon illustrating the principles of the invention. Moreover, in the figures, like reference numerals designate corresponding parts throughout the different views.

FIG. 1 illustrates one embodiment of a system according to the invention.

FIG. 2 illustrates an example of a system according to the invention comprising three parallel sources each configured with external resistive power sensing elements.

FIG. 3 illustrates another example of a system according to the invention, wherein power sensing elements are located internal to each source.

FIG. 4 is a flowchart of an embodiment of a method according to the invention for operating parallel power sources.

FIG. 5 is a flowchart of an embodiment of a method according to the invention for operating and regulating the output of parallel power sources.

### DETAILED DESCRIPTION

As utilized herein, terms such as “about” and “substantially” and “nearly” are intended to allow some leeway in mathematical exactness to account for tolerances that are acceptable in the trade. Accordingly, any deviations upward or downward from the value modified by the terms “about” or “substantially” or “approximately” in the range of 1% to 25% or less should be considered to be explicitly within the scope of the stated value.

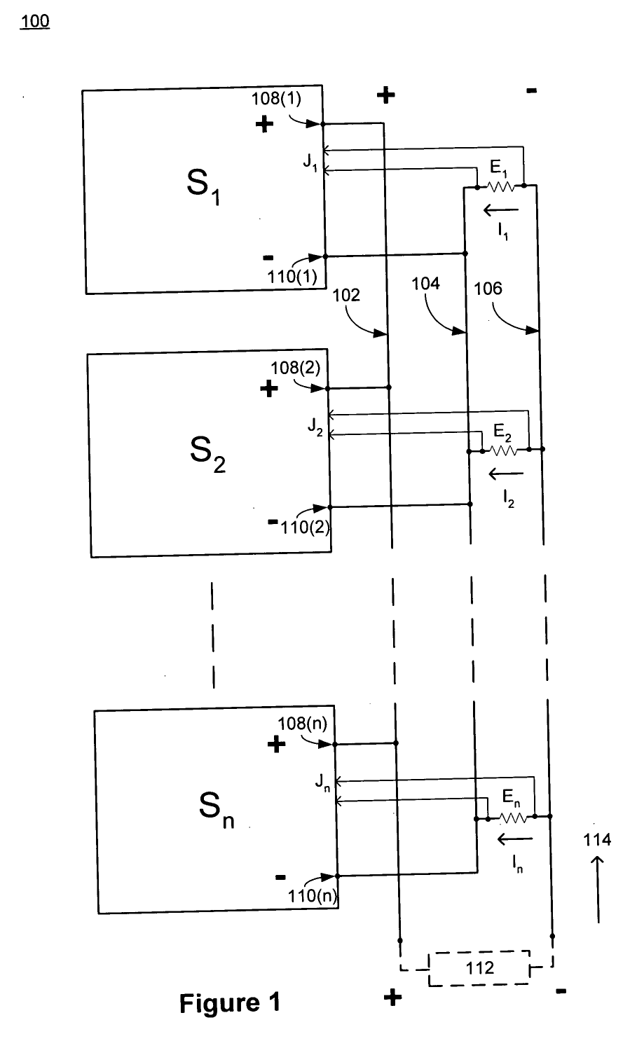

FIG. 1 illustrates an embodiment of a system 100 according to the invention. The system comprises n power sources configured electrically in parallel, wherein n is an integer of two or more. In FIG. 1, the n power sources are identified as S₁, S₂, . . . Sₙ. The system 100 further comprises a first bus 102, a second bus 104, and a third bus 106. In system 100, each source S₁, S₂, . . . Sₙ is configured with a pair of output terminals having opposite polarities: a positive output terminal 108(1), 108(2), . . . 108(n), and a negative output terminal 110(1), 110(2), . . . 110(n). Each of the positive terminals 108(1), 108(2), . . . 108(n) is coupled to first bus 102, and each of the negative terminals 110(1), 110(2), . . . 110(n) is coupled to second bus 104.

The system 100 further comprises n sensing elements E₁, E₂, . . . Eₙ, each corresponding, respectively, to one of the power sources S₁, S₂, . . . Sₙ. Each sensing element is coupled to the third bus 106. In the embodiment shown, each sensing element is also coupled between the second and third busses, but it should be appreciated that other coupling configurations are possible, such as where the sensing elements are coupled between the first and third busses. Each of the sensing elements E₁, E₂, . . . Eₙ is configured to allow sensing of the portion of the overall load demand to be met by the corresponding power source S₁, S₂, . . . Sₙ. In one embodiment, each of the elements E₁, E₂, . . . Eₙ is configured to allow sensing of the electrical current flow required from the corresponding power source S₁, S₂, . . . Sₙ by a load, and to allow derivation of respective control signals J₁, J₂, . . . Jₙ, at the corresponding power sources S₁, S₂, . . . Sₙ whereby each control signal is representative of the current flow through its corresponding power sensing element E₁, E₂, . . . Eₙ when the system 100 is in operation. Each source S₁, S₂, . . . Sₙ is configured with a means for regulating its output current responsive to the corresponding control signal J₁, J₂, . . . Jₙ. In one implementation, the sensing elements E₁, E₂, . . . Eₙ are all resistors, and the control signals J₁, J₂, . . . Jₙ are each derived from the common voltage drop across each of the resistors. In FIG. 1, for example, assuming the sensing element E₁ is a resistor having a resistance R, the voltage drop across E₁ is V=I₁×R. The corresponding power source may derive the control signal from the common voltage drop (which may be sensed at any arbitrary location between the third bus and either of the first and second busses) and the resistance of the resistor corresponding to the power source. In one embodiment, the resistance of the resistor corresponding to a power source is stored at the power source. The power source senses the common voltage drop between the two busses, and divides it by the resistance of its corresponding resistor to arrive at an estimate of the current demanded from it by the load. The power source then derives the control signal from this estimated current.

In the embodiment illustrated in FIG. 1, when the system 100 is in operation, a load 112 is coupled between first bus 102 and third bus 106, but it should be appreciated that other coupling configurations are possible, such as a configuration where the load 112 is coupled between the second bus 104 and the third bus 106. (The load 112 and its interconnections to the system 100 are shown in phantom in FIG. 1 since they are distinct and separate from the system 100). The load 112 demands bulk power from system 100, without preference among any of the sources S₁, S₂, . . . Sₙ for a particular source of load current 114. Thus, load 112 draws an aggregate load current 114 from sources S₁, S₂, . . . Sₙ, where current 114 is the aggregation of currents I₁, I₂, . . . Iₙ originating from each of the respective sources S₁, S₂, . . . Sₙ. Each individual current I₁, I₂, . . . , or Iₙ flows through its corresponding power sensing element E₁, E₂, . . . or Eₙ. The contribution to the load current 114 from each of the sources S₁, S₂, . . . Sₙ is controlled by the current regulation means corresponding to each such source, and is determined responsive to the control signal J₁, J₂, . . . Jₙ corresponding to that source. As the demand for load current 114 varies up or down, each sensor E₁, E₂, . . . Eₙ allows sensing of the changing load condition in proportion to the amount of current contributed by its corresponding source S₁, S₂, . . . Sₙ. In this manner, each source in the parallel scheme regulates its output current independently, without reliance on any control signal that may be common to more than one source. Accordingly, unlike conventional systems, system 100 is not or less susceptible to single point failures.

For example, consider a scenario in which a single point failure occurs at power sensing element E₁. As a result of the failure, no current flows through element E₁, and, in response, the output of S₁ reduces to zero. At the same time, the current demand on sources S₂, . . . Sₙ increases to compensate for the loss of the contribution from source S₁. Power sensors E₂, . . . Eₙ allow sensing of the increase in demand and also allow derivation of corrective control signals J₂, . . . Jₙ at their corresponding sources S₂, . . . Sₙ. Each of these sources increases its output current accordingly, thereby substantially maintaining load current 114 at the desired level when the system reaches a steady state condition. The same result holds true for a failure occurring at any other current sensing element E₂, . . . Eₙ.

As another example, consider a single point failure equivalent to a power failure at any one of the sources S₁, S₂, . . . Sₙ, such as an open circuit condition occurring at an output terminal, 108 or 110, of source S₁. Again, the result is a loss of the affected source, while the remaining sources S₂, . . . Sₙ respond to a demand for an increase in current contributions. However, in this type of failure scenario, in order for the remaining sources S₂, . . . Sₙ to increase their current output to meet the demand, it is essential that no portion of load current 114 flow through the power sensor corresponding to the failed source, which in this example is sensor E₁. It is therefore necessary to provide an interlock (not shown) that disconnects from load path 106 (i.e. the third bus) any sensor that corresponds to a failed source. Thus, in this example, when source S₁ fails, sensor E₁ is disconnected and I₁ goes to zero. As a result, each load current I₂, . . . Iₙ increases, and accordingly, each element E₂, . . . Eₙ allows derivation of a corrective control signal J₂, . . . Jₙ at its corresponding power source S₂, . . . Sₙ. After a brief transient condition, the system stabilizes at which point sources S₂, . . . Sₙ share the load in some proportion. In this manner, the operation of system 100 remains substantially unaffected by the failure.

Each source S₁, S₂, . . . or Sₙ may be any device capable of generating or distributing electrical power. Examples of the power sources which are possible include AC power sources, DC power sources, generators, transformers, batteries, inverters, power supplies, solar panels, and fuel cells. In one implementation, the power sources are metal/air fuel cells, which have power capacities that change over time as fuel is consumed while delivering power to a load. For additional information on metal/air fuel cells, the reader is referred to the following patents and patent applications, which disclose a particular embodiment of a metal/air fuel cell in which the metal is zinc: U.S. Pat. Nos. 5,952,117; 6,153,328; and 6,162,555; and U.S. patent application Ser. Nos. 09/521,392; 09/573,438; and 09/627,742, each of which is incorporated herein by reference as though set forth in full.

In one embodiment of system 100, sources S₁, S₂, . . . Sₙ have identical power capacities P₁=P₂= . . . =Pₙ. In a second embodiment, two or more of the sources have different power capacities. In a third embodiment, two or more of the sources have different power capacities and each of the sensing elements E₁, E₂, . . . Eₙ varies in accordance with the power capacity of the corresponding source S₁, S₂, . . . Sₙ. In one implementation, the sensing elements E₁, E₂, . . . Eₙ are each current sensing elements such as resistors having a resistance which is inversely proportional to the power capacity of the corresponding source. In this implementation, the ratio Iⱼ:Iₖ of the contributions of load current supplied by any two sources is substantially equivalent to the ratio Pⱼ:Pₖ of the power capacities of the same two sources. That is achieved because the total load current I_{L} will divide into branch currents I₁, I₂, . . . Iₙ that flow through each corresponding sensing element E₁, E₂, . . . Eₙ according to the well-known current divider rule for current flow through parallel resistors. One skilled in the art will recognize that the inverse relationship of the resistance of each branch to the power capacity of its corresponding source will result in each branch current having a magnitude in direct proportion to its corresponding power capacity.

The sensing elements E₁, E₂, . . . Eₙ can be any instrument capable of allowing sensing of power demanded by the load from the corresponding power source S₁, S₂, . . . Sₙ. In one embodiment, the sensing elements E₁, E₂, . . . Eₙ are current sensing elements. Examples of current sensing elements which are possible include resistors, current transducers that allow sensing of current by means of magnetic induction, and current transducers that comprise Hall effect sensors. In one implementation, the type of sensing elements which are employed in relation to the sources S₁, S₂, . . . Sₙ are identical. In a second embodiment, the types of elements which are employed may vary among the individual power sources S₁, S₂, . . . Sₙ. Other implementations include current sensors that comprise any one of the above current sensing technologies having an impedance that is inversely proportional to the power capacity of the power source corresponding to the current sensor.

In one implementation, the power sources S₁, S₂, . . . Sₙ are each DC power sources, and the sensing elements E₁, E₂, . . . Eₙ are each configured to allow sensing of the magnitude of the current originating from the corresponding power source. In this implementation, the control signals J₁, J₂, . . . Jₙ are each representative of the magnitude of the current required from the corresponding power source. In a second implementation, the power sources S₁, S₂, . . . Sₙ are each AC power sources, and the sensing elements E₁, E₂, . . . Eₙ are each configured to allow sensing of the magnitude and/or the phase of the current required from the corresponding power source. In this implementation, the control signals J₁, J₂, . . . Jₙ are each representative of the magnitude and/or phase of the current required from the corresponding power source. In one example, each control signal is a complex value representing both the magnitude and phase of the corresponding current.

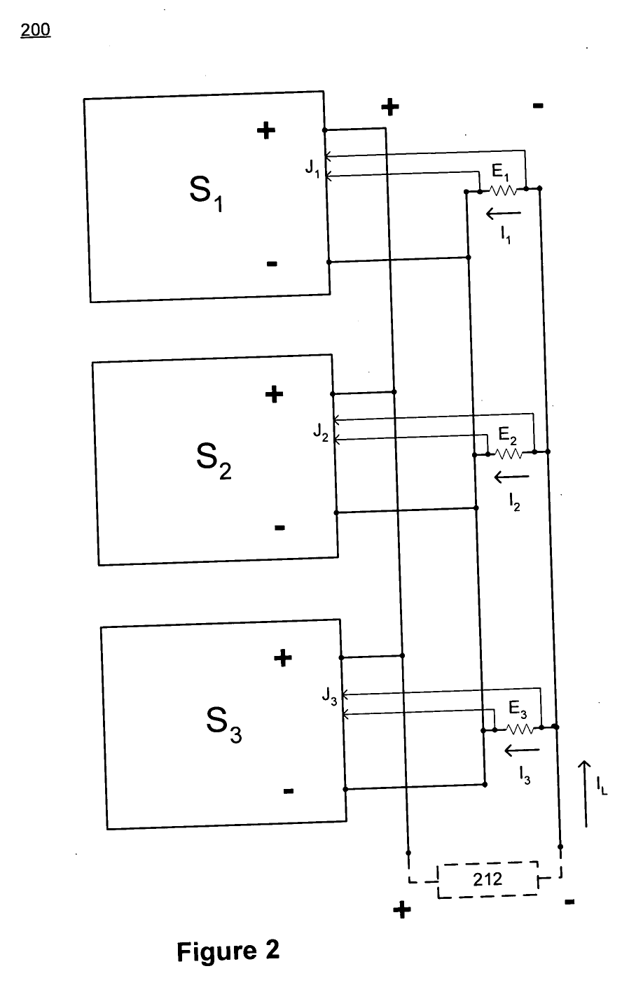

FIG. 2 illustrates an example of a system 200 according to the invention comprising three parallel sources S₁, S₂, and S₃ collectively delivering a load current I_{L} to a load 212. Current I_{L} comprises the aggregation of individual currents I₁, I₂, and I₃, originating respectively from sources S₁, S₂, and S₃. The currents respectively flow through external sensing elements E₁, E₂, and E₃, corresponding respectively to sources S₁, S₂ and S₃. Each element E₁, E₂, and E₃ comprises a resistor having a resistance value inversely proportional to the capacity of its corresponding source. In one configuration, a sizing standard is utilized such that the ratio of the resistances of any two sensing elements is inversely related to the ratio of the power capacities of the corresponding sources. The sizing standard should be selected to produce resistance values that are compatible with both the interfacing load circuitry and the interfacing current sensing circuitry. Thus, for example, assume the sources have capacities, or power ratings, of S₁=P, S₂=5P, and S₃=10P, and assume the resistive element E₁ has a nominal resistance value of R. A sizing standard can then be selected to determine the proper resistance values of the resistive elements for any source in the parallel system. In this example, for a power source having a power capacity of nP, the resistance of its corresponding a resistive element is R/n, where n is any real number. The resistances of the other two sensing elements will be as follows: E₂=0.2R, and E₃=0.1R. Those skilled in the art will recognize that, under these conditions, the load current I_{L} will divide among the sources S₁, S₂, S₃ in proportion to their respective capacities. In other words, the following allocation of the load current I_{L} will result: I₁=1/16 I_{L}, I₂=5/16 I_{L}, and I₃=10/16 I_{L}.

One of skill in the art will appreciate, from a reading of this disclosure, that additional sources can be added to the system 200 to increase the capacity of the overall system. Assuming that each such source is configured with a corresponding resistive current sensing element having a resistance inversely proportional to the power capacity of the corresponding power source in accordance with the same sizing standard, each such source will contribute a percentage of the overall load current in direct proportion to the ratio of its capacity to the capacity of the parallel system. This results in a desirable balancing or distribution of load currents, and contributes to a situation whereby each power source operates at or near its optimal efficiency range. Problems endemic in the prior art such as accelerated aging due to thermal and electrical overstress arising from sustained operation outside of rated limits are thereby avoided.

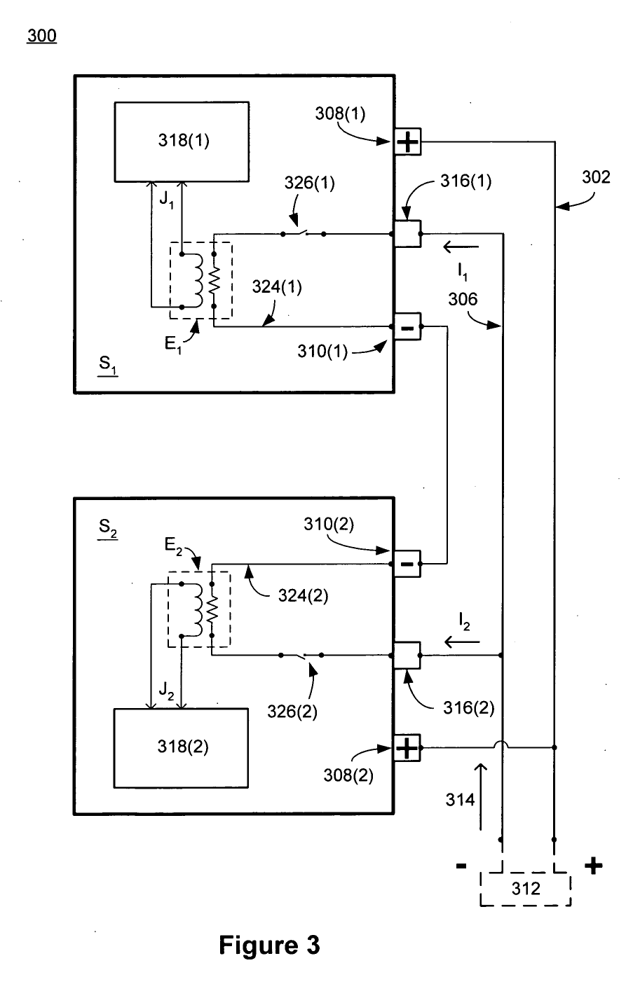

FIG. 3 shows another example of a system 300 according to the invention. System 300 comprises two parallel connected sources, S₁ and S₂, having respective positive output terminals 308(1) and 308(2), respective negative output terminals 310(1) and 310(2), and respective third output terminals 316(1) and 316(2). Note that, for simplicity, the internal power transmitting or power generating circuitry coupled to the positive and negative output terminals is not shown. Each source S₁ or S₂ is also configured with an internal power sensing element, E₁ or E₂ respectively. In this particular example, the parallel connection of sources S₁ and S₂ is made by coupling the positive terminals 308(1) and 308(2) to a first bus 302, and by coupling the negative terminals 310(1) and 310(2) to a second bus 304. Bus bars 324(1) and 324(2), respectively located internally to each source, S₁ and S₂ as the case may be, respectively couple the negative terminals 310(1) and 310(2) to the respective third terminals 316(1) and 316(2). Terminals 316(1) and 316(2) are each coupled to a third bus 306. Together, sources S₁ and S₂ are configured to deliver load current 314 to a load 312 connected across first bus 302 and third bus 306.

In this particular example, the load current 314 is the aggregation of individual currents I₁ and I₂, contributed respectively by sources S₁ and S₂. Bus bars 324(1) and 324(2) respectively conduct I₁ and I₂ through sensing elements E₁ and E₂ located internally to respective sources S₁ or S₂. Elements E₁ and E₂ transmit control signals J₁ and J₂, respectively, to internal current regulator circuits 318(1) and 318(2), which may be any type of current regulation circuit known in the art and suitable for the purpose of regulating the output current I₁ or I₂ by means of feedback control to achieve a desired transfer characteristic. Each bus bar 324(1) or 324(2) is configured with an interlock, 326(1) or 326(2), which may be any conventional electrical and/or mechanical interlock capable of interrupting current flow by opening an electrical circuit responsive to a condition occurring in another circuit location. For example, in this embodiment, interlock 326(1) or 326(2), in response to a power failure (i.e. a loss of power output) of its corresponding source, opens its corresponding bus bar 324(1) or 324(2). Interlock 326(1) or 326(2) thereby ensures that no portion of load current 314 will flow from third bus 306 through a sensor, E₁ or E₂, when power output from its corresponding power source, S₁ or S₂, becomes unavailable. By way of example only, each interlock 326(1) and 326(2) is shown in FIG. 3 configured as a circuit breaker (or equivalent circuit breaking device) located on its corresponding bus bar 324(1) or 324(2). However, one skilled in the art will recognize that the location and configuration of an interlock 324(1) and 324(2) may vary, provided that the interlock interrupts current flow through its corresponding current sensor, E₁ or E₂, responsive to a loss of power output from source S₁ or S₂. In addition, an interlock 324(1) or 324(2) may optionally comprise a second circuit breaking device (not shown) that is configured to disconnect its corresponding power source, S₁ or S₂, from load 312 responsive to the same loss of power condition.

The configuration of the particular example of the system 300 shown in FIG. 3 provides several practical advantages. First, because the sensing elements are located internally to the corresponding power sources, the current sensing function may be performed within a controlled and shielded environment, thereby reducing errors introduced by thermal, electrical, or magnetic interference. Second, the configuration permits a modular construction for sources S₁ and S₂. A modular construction is beneficial because it allows for rapid and cost-effective manufacture and incorporation into existing dual-bus distribution schemes. Third, internal location of the sensing element facilitates the inclusion of an electrical and/or mechanical interlock that is necessary for disconnecting the current sensing element from the bus in the event of a loss of power output. For these reasons, parallel power sources of modular construction having internal current sensing elements comprise a preferred embodiment of a system according to the invention.

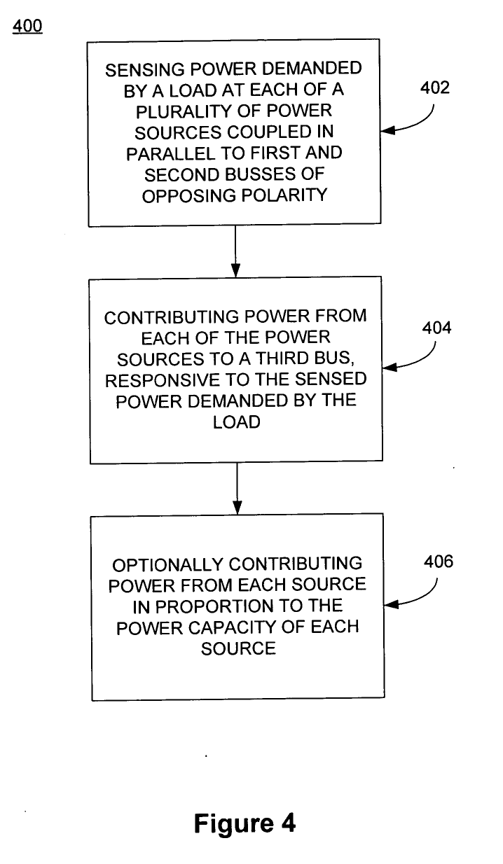

FIG. 4 is a flowchart of an embodiment of a method 400 according to the invention of delivering power to a load from a parallel configuration of power sources. Step 402 is a sensing step, wherein power demanded by a load is individually sensed at each of a plurality of power sources that are connected electrically in parallel. As discussed previously in relation to the system embodiments of the invention, the plurality of power sources may each comprise AC sources, or they may each comprise DC sources; and the power sources may have identical power capacity ratings, or two or more of the power sources may have different power capacity ratings. The sensing may be accomplished by any suitable means, such as those discussed previously in relation to the system embodiments of the invention. Next, a contributing step is performed in step 404. In this step, the plurality of power sources each individually contribute power in response the power demand of the load as individually sensed in step 402. Optionally, step 406 is also performed concurrently with step 404. In step 406, the power individually provided by each source in step 404 is provided in proportion to the power capacity of the source. One of skill in the art will appreciate from a reading of this disclosure that the steps illustrated in FIG. 4 may be performed in orders different from that illustrated in FIG. 4. For example, it is possible for one or more of these steps to be performed simultaneously, concurrently or in parallel.

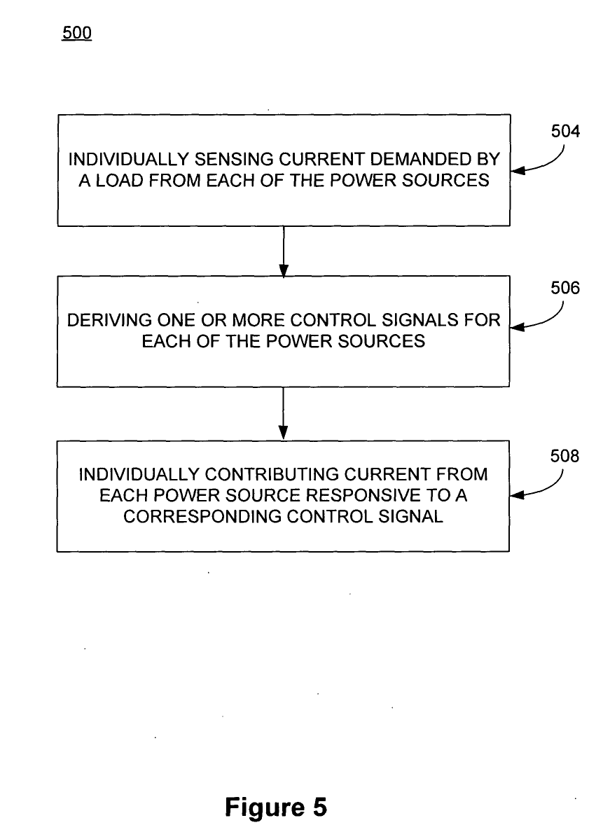

FIG. 5 is a flowchart of an example of a method 500 according to the invention of delivering current to a load from a plurality of power sources coupled in parallel to first and second busses. The method begins with step 504. In step 504, the method comprises individually sensing current demanded by a load from each of the power sources. This sensing is enabled by means of a current sensing element corresponding to each of the power sources and coupled to a third bus. As discussed previously in relation to the system embodiments, in the case in which the power sources are DC power sources, sensing step 504 may comprise individually sensing the magnitude of the current demanded from each of the power sources. In the case in which the power sources are AC power sources, sensing step 504 may comprise individually sensing the magnitude and/or phase of the current demanded from each of the power sources. Step 506 follows step 504. In step 506, one or more control signals corresponding to each of the power sources are derived from the current demanded by the load from the power source as sensed in the previous step. Step 508 follows step 506. Step 508 comprises individually contributing current from each of the power sources responsive to a control signal corresponding to each source. One of skill in the art will appreciate from a reading of this disclosure that the steps illustrated in FIG. 5 may be performed in orders other than those illustrated in FIG. 5. For example, it is possible for one or more of these steps to be performed simultaneously, concurrently, or in parallel.

While various embodiments of the invention have been described, it will be apparent to those of ordinary skill in the art that many more embodiments and implementations are possible that are within the scope of this invention. Accordingly, the invention is not to be restricted except in light of the attached claims and their equivalents.

What is claimed is:

1. A power system comprising:
a plurality of power sources coupled in parallel to a first bus having a polarity and a second bus having an opposing polarity;
a third bus; and
a plurality of sensing elements, each sensing element in the plurality of sensing elements corresponding to one of the power sources in the plurality of power sources, each sensing element coupled to the third bus, and configured to allow sensing of power demanded by a load from the corresponding power source,
and each power source configured to sense power demanded from it by the load, and supply power to the load in response thereto.

2. The system of claim 1 wherein at least one of the power sources in the plurality of power sources is a DC power source.

3. The system of claim 2 wherein the at least one DC power source comprises a metal/air fuel cell.

4. The system of claim 1 wherein at least one of the power sources in the plurality of power sources is an AC power source.

5. The system of claim 1 wherein two or more of the power sources in the plurality of power sources have different power capacities.

6. The system of claim 1 wherein at least one of the power sources is configured to contribute power to the third bus responsive to a signal derived from the corresponding sensing element.

7. The system of claim 6 wherein at least one of the power sources regulates its power by means of a regulator circuit.

8. The system of claim 1 wherein at least one of the sensing elements is internal to its corresponding power source.

9. The system of claim 1 wherein at least one of the sensing elements in the plurality of sensing elements comprises a resistor coupled between the third bus and either the first and second busses.

10. The system of claim 9 wherein a power source senses the power demanded from it by the load in the form of a common voltage drop between the third bus and either of the first and second busses, and the value of the resistance of its corresponding resistor.

11. The system of claim 10 wherein the power source senses the common voltage drop from an arbitrary location between the third bus and either of the first and second busses.

12. The system of claim 9 wherein the resistor has a resistance which is inversely proportional to the power capacity of its corresponding power source.

13. The system of claim 1 wherein at least one sensing element in the plurality of sensing elements provides an impedance between busses that is inversely proportional to a power capacity of the power source, the power source corresponding to the at least one sensing element.

14. The system of claim 13 wherein the at least one sensing element comprises an inductive current transducer.

15. The system of claim 13 wherein the at least one sensing element comprises a Hall Effect current transducer.

16. The system of claim 1 wherein each of the power sources has a power capacity and each of the sensing elements provides an impedance between busses that is inversely proportional to the power capacity of its corresponding power source, whereby each sensing element senses power demanded by the load in proportion to the power capacity of its corresponding power source.

17. The system of claim 16 wherein each power source supplies a portion of current demanded by the load such that a ratio of the power capacities of any two of the power sources is substantially equivalent to a ratio of the portions of load current supplied by the same two sources.

18. The system of claim 1 wherein at least one power source of the plurality of power sources further comprises an interlock that interrupts current flow through the current sensing element corresponding to the at least one power source, responsive to a power failure of the at least one power source.

19. The system of claim 18 wherein the interlock disconnects the at least one power source from the load, responsive to a power failure of the at least one power source.

20. A method of delivering power to a load from a plurality of power sources coupled in parallel comprising:
individually sensing at each of the power sources power demanded by a load; and
individually contributing power to the load from each of the power sources responsive to the power demand as sensed at the power source.

21. The method of claim 20 wherein at least one of the power sources in the plurality of power sources is a DC power source.

22. The method of claim 21 wherein the at least one DC power source comprises a metal/air fuel cell.

23. The method of claim 20 wherein at least one of the power sources in the plurality of power sources is an AC power source.

24. The method of claim 20 wherein two or more of the power sources have different power capacities, and the individual contributing step comprises contributing from each of the power sources current in direct proportion to a ratio of the power capacity of the contributing power source to a total power capacity of all of the power sources.

25. The method of claim 20 wherein the individual contributing step further comprises contributing current from each of the power sources responsive to a signal derived from the current sensed at the power source.

26. The method of claim 25 further comprising providing a current sensing element internal to at least one power source.

27. The method of claim 26 wherein at least one of the current sensing elements comprises a resistor.

28. The method of claim 27 wherein the resistor enables sensing of current in the form of a common voltage drop.

29. The method of claim 28 wherein the resistor has a resistance which is inversely proportional to the power capacity of the power source containing the resistor.

30. The method of claim 26 wherein at least one of the current sensing elements provides an impedance between busses that is inversely proportional to the power capacity of the at least one power source.

31. The method of claim 30 wherein the at least one current sensing element comprises an inductive current transducer.

32. The method of claim 30 wherein the at least one current sensing element comprises a Hall Effect current transducer.

33. The method of claim 20 wherein the sensing step further comprises sensing magnitude and phase of current demanded by the load.

34. The method of claim 33 further comprising regulating current contributed from at least one of the power sources responsive to a signal derived from the magnitude of current sensed at the at least one power source.

35. The method of claim 33 further comprising regulating current contributed from at least one of the power sources responsive to a signal derived from the phase of current sensed at the at least one power source.

36. The method of claim 33 further comprising regulating current contributed from at least one of the power sources responsive to a signal derived from the magnitude and phase of current sensed at the at least one power source.

37. A method of delivering power to a load from a plurality of power sources coupled in parallel to first and second busses, comprising:
providing a power sensing element corresponding to each of the power sources and coupled to a third bus;
individually sensing power demanded by the load from each of the power sources;
individually deriving one or more control signals at each of the power sources responsive to the power demanded by the load from that power source; and
individually contributing power from each power source responsive to the control signal corresponding to the power source.

38. The method of claim 37 further comprising individually sensing current demanded by the load from each of the power sources, wherein each of the power sensing elements comprises a current sensing element.

39. The method of claim 38 wherein the current from each of the power sources has a magnitude, and the sensing step comprises individually sensing the magnitude of the current demanded from each of the power sources.

40. The method of claim 38 wherein the current from each of the power sources has a magnitude and phase, and the sensing step comprises individually sensing the phase of the current demanded from each of the power sources.

41. The method of claim 38 wherein the current from each of the power sources has a magnitude and phase, and the sensing step comprises individually sensing the magnitude and phase of the current demanded from each of the power sources.

42. The method of claim 38 further comprising providing at least one of the power sources with an interlock that interrupts current flow through the current sensing element corresponding to the at least one power source responsive to a power failure of the at least one power source.

43. The method of claim 42 wherein the interlock disconnects the at least one power source from the load responsive to a power failure of the at least one power source.
